(19) United States
(12) Patent Application Publication
(10) Pub. No.: US 2005/0135142 A1
(43) Pub. Date: Jun. 23, 2005

(54) Storage circuit, semiconductor device, electronic apparatus, and driving method

(75) Inventor: Yasunori Koide, Matsumoto-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/008,618

(22) Filed: Dec. 10, 2004

(30) Foreign Application Priority Data
Dec. 19, 2003 (JP) 2003-423222

(51) Int. Cl. G11C 11/22

(52) U.S. Cl. 365/145

(57) ABSTRACT

To provide a storage circuit that can readily and stably read memory data, in storage circuits that are used mainly in program circuits. A storage circuit equipped with a flip-flop having a first terminal and a second terminal, a first ferroelectric capacitor that gives a first capacity to the first terminal, a second ferroelectric capacitor that gives a second capacity different from the first capacity to the second terminal, and a voltage source that starts supplying a driving voltage for driving the flip-flop to the flip-flop when the first capacity and the second capacity are given to the first terminal and the second terminal, respectively. Complementary data are preferably be written in the first ferroelectric capacitor and the second ferroelectric capacitor.

### BACKGROUND

The present invention relates to storage circuits, semiconductor devices, electronic apparatuses, and driving methods. In particular, the present invention relates to storage circuits that can readily read memory data, semiconductor devices and electronic apparatuses equipped with the same, and methods for driving the same.

A conventional memory cell is disclosed in Japanese Laid-open Patent Application 64-66899 (Patent Document 1). The memory cell disclosed in the aforementioned Patent Document 1 is equipped with a static cell having two internal nodes, and a nonvolatile section having two ferroelectric capacitors. Then, by applying a voltage to the ferroelectric capacitors to the extent that the ferroelectric capacitors causes polarity inversion, a voltage on one of the internal nodes rises slightly higher than a voltage on the other of the internal nodes. By this, data is transferred from the nonvolatile section to the static cell.
[Patent Document 1] Japanese Laid-open Patent Application SHO 64-66899

### SUMMARY

However, in the conventional memory cell described in the aforementioned Patent Document 1, for transferring data from the nonvolatile section to the static cell, it is necessary to pre-charge the bit line and to apply the voltage to the ferroelectric capacitors. This causes a problem in that its operation becomes complex. Also, in the conventional memory cell described in the aforementioned Patent Document 1, although the voltage on one of the internal nodes becomes higher than the voltage on the other of the internal nodes, their difference is small. Therefore, there is a problem in that, if there are manufacturing variations in the threshold voltage of transistors composing the static cell, the static cell may malfunction.

Accordingly, it is an object of the present invention to provide storage circuits, semiconductor devices, electronic apparatuses, and driving methods, which can solve the problems described above. This object can be achieved by combining the characteristics set forth in the independent claims in the scope of patent claims. Also, the dependent claims further define advantageous concrete examples of the present invention.

To achieve the aforementioned object, in accordance with a first embodiment of the present invention, there is provided a storage circuit characterized in comprising: a flip-flop having a first terminal and a second terminal; a first ferroelectric capacitor that gives a first capacity to the first terminal; a second ferroelectric capacitor that gives a second capacity different from the first capacity to the second terminal; and a voltage source that starts supplying a driving voltage for driving the flip-flop to the flip-flop in which the first capacity and the second capacity are given to the first terminal and the second terminal, respectively.

With the structure described above, when a driving voltage is supplied to the flip-flop, potentials on the first terminal and the second terminal elevate according to the first capacity and the second capacity, respectively. In other words, the potentials on the first terminal and the second terminal elevate according to the capacities based on paraelectric characteristics of the first ferroelectric capacitor and the second ferroelectric capacitor, respectively. Accordingly, memory data to be retained by the flip-flop is set according to the first capacity and the second capacity. Accordingly, by the structure described above, there can be provided a storage circuit that can readily store memory data by setting the first capacity and the second capacity, and that can readily read the memory data with a very simple structure.

In accordance with a second embodiment of the present invention, there is provided a storage circuit characterized in comprising: a flip-flop having a first terminal and a second terminal; a first ferroelectric capacitor that gives a first capacity to the first terminal; a second ferroelectric capacitor that gives a second capacity different from the first capacity to the second terminal; and a short-circuit section that controls as to whether or not the first terminal and the second terminal are to be electrically connected. In this case, the storage circuit may preferably be further equipped with a connecting section that controls as to whether or not the flip-flop is to be electrically connected to the first ferroelectric capacitor and the second ferroelectric capacitor, wherein the short-circuit section may electrically cut off the first terminal and the second terminal corresponding to a timing at which the connecting section electrically connects the flip-flop to the first ferroelectric capacitor and the second ferroelectric capacitor.

With the structure described above, the potential on the first terminal and the potential on the second terminal can be brought to generally the same potential. In other words, with the structure described above, the potentials on the first terminal and the second terminal can be controlled based on the first capacity and the second capacity, from the state in which the potentials on the first terminal and the second terminal are at the same potential. Accordingly, with the structure described above, there can be provided a storage circuit that can stably read memory data with a very simple structure.

Also, with the structure described above, before the first capacity and the second capacity are charged, the short-circuit section electrically cuts off the first terminal and the second terminal. Accordingly, with the structure described above, the potentials on the first terminal and the second terminal can be effectively controlled based on a capacity difference between the first capacity and the second capacity. Accordingly, with the structure described above, there can be provided a storage circuit that can read memory data more stably.

In accordance with a third embodiment of the present invention, there is provided a storage circuit characterized in comprising: a first clocked inverter having an input terminal and an output terminal; a second clocked inverter that inverts a signal outputted from the output terminal and supplies the signal to the input terminal; a first ferroelectric capacitor that gives a first capacity to the input terminal; a second ferroelectric capacitor that gives a second capacity different from the first capacity to the output terminal; and a control section that controls as to whether or not the first clocked inverter and the second clocked inverter are to be operated. In this case, the storage circuit may preferably be further equipped with a voltage source that supplies a driving voltage to the first clocked inverter and the second clocked inverter, wherein the control section may preferably operate the first clocked inverter and the second clocked inverter after a potential of the driving voltage exceeds a threshold voltage of the first clocked inverter and the second clocked inverter.

With the structure described above, the timing to raise and/or lower the potentials of the first terminal and the second terminal based on the first capacity and the second capacity can be controlled by a control signal. With the structure described above, after the operation of the storage circuit becomes stable, such as, for example, after the power supply voltage that is supplied to the first clocked inverter and the second clocked inverter becomes stable, the potential on the first terminal and the second terminal can be controlled. Accordingly, there can be provided a storage circuit that can stably read memory data with a very simple structure.

The storage circuit may preferably be further equipped with a discharge section that brings both ends of the first ferroelectric capacitor and the second ferroelectric capacitor to generally the same potential. With the structure described above, the voltage that is to be applied to the first ferroelectric capacitor and the second ferroelectric capacitor can be brought to about 0V. Accordingly, deterioration of the first ferroelectric capacitor and the second ferroelectric capacitor can be suppressed.

In accordance with a fourth embodiment of the present invention, there is provided a storage circuit characterized in comprising: a flip-flop having a first terminal and a second terminal; a first ferroelectric capacitor that gives a first capacity to the first terminal; a second ferroelectric capacitor that gives a second capacity different from the first capacity to the second terminal; a first switch that short-circuits both ends of the first ferroelectric capacitor; and a second switch that short-circuits both ends of the second ferroelectric capacitor.

Complementary data may preferably be written in the first ferroelectric capacitor and the second ferroelectric capacitor. With the structure described above, the first capacity and the second capacity can be combined according to combinations of data to be written in the first ferroelectric capacitor and the second ferroelectric capacitor, respectively. Accordingly, a desired capacity difference can be readily given across the first terminal and the second terminal.

In accordance with a fifth embodiment of the present invention, there is provided a semiconductor device characterized in comprising the storage circuit described above. It is noted here that the semiconductor device generally refers to a device composed of semiconductor, which is quipped with a storage circuit in accordance with the present invention, and is not particularly limited in its structure, but may include a variety of devices that require storage devices, such as, for example, ferroelectric memory devices, DRAMs, flash memories and the like, which are equipped with the storage circuit described above.

In accordance with a sixth embodiment, there is provided an electronic apparatus characterized in comprising the semiconductor device described above. It is noted here that the electronic apparatus generally refers to an apparatus equipped with a semiconductor device in accordance with the present invention, which achieves predetermined functions, and is not particularly limited in its structure, but may include a variety of devices that require storage devices, such as, for example, computer devices in general, portable telephones, PHSs, PDAs, electronic notebooks, IC cards, and the like, which are equipped with the semiconductor device described above.

In accordance with a seventh embodiment of the present invention, there is provided a driving method for driving a storage circuit equipped with a flip-flop having a first terminal and a second terminal, the driving method characterized in comprising: a step of giving a first capacity to the first terminal; a step of giving a second capacity different from the first capacity to the second terminal; and a step of starting supplying a driving voltage to the flip-flop.

The storage circuit may preferably be equipped with a first ferroelectric capacitor having the first capacity and a second ferroelectric capacitor having the second capacity, wherein the step of giving the first capacity may preferably include a step of electrically connecting the first terminal and the first ferroelectric capacitor, and the step of giving the second capacity may preferably include a step of electrically connecting the second terminal and the second ferroelectric capacitor.

### BRIEF DESCRIPTION OF THE DRAWINGS

FIG. 1 is a diagram showing a structure of a ferroelectric memory device 500 which is an example of a semiconductor device in accordance with an embodiment of the present invention;

FIG. 2 is a diagram indicating a program circuit 100 in accordance with the a first embodiment;

FIG. 3 is a timing chart indicating operations of the program circuit 100 in accordance with the first embodiment;

FIG. 4 is a diagram indicating hysteresis characteristics of a first ferroelectric capacitor 122 and a second ferroelectric capacitor 124;

FIG. 5 is a diagram indicating a program circuit 100 in accordance with a second embodiment;

FIG. 6 is a timing chart indicating operations of the program circuit 100 in accordance with the second embodiment;

FIG. 7 is a diagram indicating a program circuit 100 in accordance with a third embodiment;

FIG. 8 is a diagram indicating a program circuit 100 in accordance with a fourth embodiment;

FIG. 9 is a timing chart indicating operations of the program circuit 100 in accordance with the fourth embodiment; and

FIG. 10 is a perspective view showing a structure of a personal computer 1000, which is an example of an electronic apparatus in accordance with an embodiment of the present invention.

### DETAILED DESCRIPTION OF EMBODIMENTS

The present invention is described below based on embodiments of the present invention with reference to the accompanying drawings. However, the embodiments described below do not in anyway limit the invention concerning the scope of patent claims, and all the combinations of the characteristics described in the embodiments would not necessarily be indispensable as the means for solution of the invention.

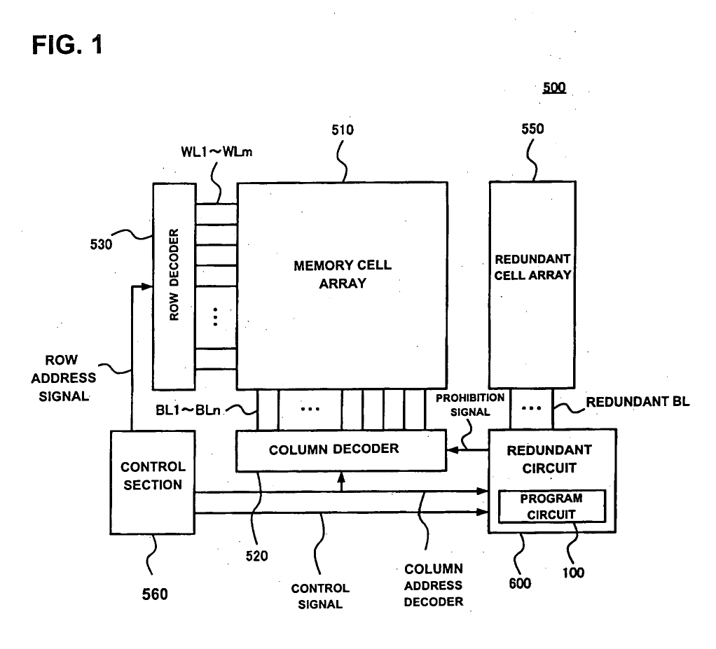

FIG. 1 is a diagram showing a structure of a ferroelectric memory device 500 which is an example of a semiconductor device in accordance with an embodiment of the present invention. The ferroelectric memory device 500 has a structure equipped with a memory cell array 510, a column decoder 520, a row decoder 530, a control section 560, a redundant array 550, and a redundant circuit 600.

The memory cell array 510 has a structure equipped with a plurality of ferroelectric capacitors disposed in an array. Each of the ferroelectric capacitors is controlled by a bit line BL and a word line WL among word lines WL1-WLm (m is an integer of 2 or greater) and bit lines BL1-BLn (n is an integer of 2 or greater), respectively. More specifically, by controlling potentials on the bit line BL and the word line WL, data written in the corresponding ferroelectric capacitor can be read, or data can be written in the corresponding ferroelectric capacitor.

The control section 560 generally controls operations of the ferroelectric memory device 500. More specifically, the control section 560 supplies row address signals and column address signals to the row decoder 530 and the column decoder 520, respectively, to read data from the ferroelectric capacitors, and to write data in the ferroelectric capacitors. Also, the control section 560 supplies control signals to the redundant circuit 600 to control a program circuit 100. Also, the control section 560 generates a driving voltage to drive the ferroelectric memory device 500, and supplies the same to various sections including the program circuit 100.

The row decoder 530 controls potentials on the word lines WL1-WLm. More specifically, the row decoder 530 receives a row address signal from the control section 560, and selects a specified word line WLj (j is an integer of 1 through m), based on the row address signal. Also, the column decoder 520 controls potentials on the bit lines BL1-BLn. More specifically, the column decoder 520 receives a column address signal from the control section 560, and selects a specified bit line BLk (k is an integer of 1 through n), based on the column address signal. By this, one of the ferroelectric capacitors corresponding to the word line WLk selected by the row decoder 530 and the bit line BLk selected by the column decoder 520.

The redundant circuit 600 has a structure having a plurality of program circuits 100. The redundant circuit 600 generates, based on an output signal and a column address signal outputted from the program circuit 100, a prohibition signal to prohibit access to a specified bit line BLk specified by the output signal and the column address signal, and supplies the same to the column decoder 520. Also, when the bit line BLk whose access is prohibited is selected, the redundant circuit 600 controls the redundant cell array 550 to select a redundant bit line BL instead of the bit line BLk. In other words, the redundant circuit 600 replaces the bit line BLk whose access is prohibited for a redundant bit line.

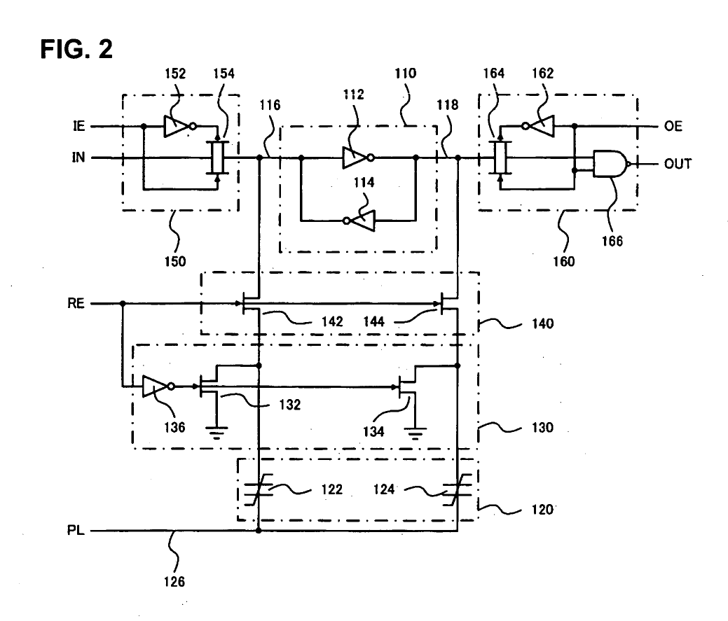

FIG. 2 is a diagram indicating the program circuit 100 in accordance with the first embodiment. The program circuit 100 has a structure equipped with a flip-flop 110, a storage section 120, a discharge section 130, a connecting section 140, a writing section 150, and an output section 160. The program circuit 100 is a circuit that reads memory data stored in the storage section 120 that is a nonvolatile storage device, and writes the data in the flip-flop 110, to thereby supply the data externally as an output signal OUT.

The flip-flop 110 has a structure having a first inverter 112 and a second inverter 114, and a first terminal 116 and a second terminal 118 that electrically connects the flip-flop 110 to external sections. Each of the first inverter 112 and the second inverter 114 has an input terminal and an output terminal, the output terminal of the first inverter 112 is electrically connected to the input terminal of the second inverter 114, and the output terminal of the second inverter 114 is electrically connected to the input terminal of the first inverter 112. Also, the input terminal of the first inverter 112 and the output terminal of the second inverter 114 are electrically connected to the first terminal 116, and the output terminal of the first inverter 112 and the input terminal of the second inverter 114 are electrically connected to the second terminal 118.

The storage section 120 has a structure having a first ferroelectric capacitor 122 and a second ferroelectric capacitor 124. Each of the first ferroelectric capacitor 122 and the second ferroelectric capacitor 124 has one end and another end. The one end of the first ferroelectric capacitor 122 is formed to be electrically connectable to the first terminal 116, and the one end of the second ferroelectric capacitor 124 is formed to be electrically connectable to the second terminal 118. Also, the other end of the first ferroelectric capacitor 122 and the other end of the second ferroelectric capacitor 124 are electrically connected to a plate line 126.

Also, the first ferroelectric capacitor 122 and the second ferroelectric capacitor 124 store complementary data, such that the first ferroelectric capacitor 122 and the second ferroelectric capacitor 124 have mutually different capacities based on their paraelectric characteristics. Accordingly, when the flip-flop 110 and the storage section 120 are electrically connected, the first ferroelectric capacitor 122 gives a predetermined capacity to the first terminal 116, and the second ferroelectric capacitor 124 gives a capacity different from the predetermined capacity to the second terminal 118.

The discharge section 130 controls the potential on one ends of the first ferroelectric capacitor 122 and the second ferroelectric capacitor 124 based on the potential of a control signal RE, thereby bringing the potential on the one ends to be generally the same potential as the potential on the other ends. More specifically, the discharge section 130 brings the potential on one end of the first ferroelectric capacitor 122 and on one end of the second ferroelectric capacitor 124 to be generally the same potential as the potential on the plate line 126, thereby bringing the voltage that is applied to the first ferroelectric capacitor 122 and the second ferroelectric capacitor 124 to almost zero (0).

In the present embodiment, the discharge section 130 has a structure having n-type MOS transistors 132 and 134, and a third inverter 136. One ends of the n-type MOS transistors 132 and 134 are grounded, and the other ends thereof are electrically connected to the first ferroelectric capacitor 122 and the second ferroelectric capacitor 124, respectively. In other words, the n-type MOS transistors 132 and 134 control, based on potentials of their gates, as to whether or not the potentials on the one ends of the first ferroelectric capacitor 122 and the second ferroelectric capacitor 124 are to be brought to the ground potential. Also, the third inverter 136 inverts the logical value of the control signal RE supplied to its input, and supplies the same to the gates of the n-type MOS transistors 132 and 134.

The connecting section 140 controls, based on the potential of the control signal RE, as to whether or not the flip-flop 110 and the storage section are to be electrically connected. In other words, the connecting section 140 controls as to whether or not the first ferroelectric capacitor 122 is to be electrically connected to the first terminal 116, and the second ferroelectric capacitor 124 to the second terminal 118.

In the present embodiment, the connecting section 140 has a structure having n-type MOS transistors 142 and 144. The n-type MOS transistor 142 has one of its source and drain electrically connected to the first ferroelectric capacitor 122, and the other electrically connected to the first terminal 116. Thus, the n-type MOS transistor 142 controls, based on the potential on its gate, as to whether or not the first ferroelectric capacitor 122 is to be electrically connected to the first terminal 116. Also, the n-type MOS transistor 144 has one of its source and drain electrically connected to the second ferroelectric capacitor 124, and the other electrically connected to the second terminal 118. Thus, the n-type MOS transistor 144 controls, based on the potential on its gate, as to whether or not the second ferroelectric capacitor 124 is to be electrically connected to the second terminal 118.

The writing section 150 writes memory data in the flip-flop 110, based on potentials of control signals IE and IN. The writing section 150 has a structure having a fourth inverter 152, and a transfer gate 154. The fourth inverter 152 receives the control signal IE as an input, and supplies a signal of the inverted control signal IE to the gate of a p-type MOS transistor composing the transfer gate 154. The transfer gate 154 has one end that is supplied with the control signal IN, and the other end that is electrically connected to the first terminal 116. Also, the control signal IE is supplied to the gate of an n-type MOS transistor composing the transfer gate 154. In other words, the writing section 150 controls, based on the potential of the control signal IE, as to whether the control signal IN is to be supplied to the first terminal 116, thereby controlling the potential on the first terminal 116. By this, predetermined memory data can be written in the flip-flop 110.

The output section 160 outputs, based on the potential of a control signal OE, an output signal OUT indicating the memory data written in the flip-flop 110. In the present embodiment, the output section 160 has a structure having a fifth inverter 162, a transfer gate 164, and a NAND circuit 166.

The fifth inverter 162 receives the control signal OE as an input, and supplies a signal that is the inverted control signal OE to the gate of a p-type MOS transistor composing the transfer gate 164. The transfer gate 164 has its one end electrically connected to the second terminal 118, and the other end electrically connected to one of the input terminal of NAND circuit 166. Also, the control signal OE is supplied to the gate of an n-type MOS transistor composing the transfer gate 164. The NAND circuit 166 outputs a negative logical product of the control signal OE and the potential on the other terminal of the transfer gate 164 as an output signal OUT.

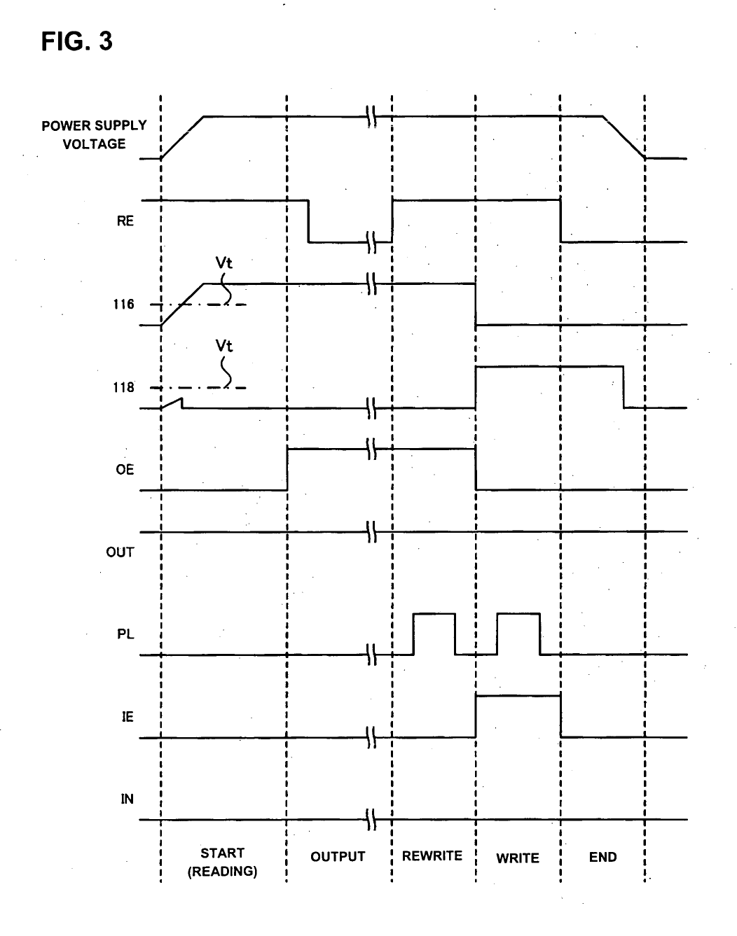

FIG. 3 is a timing chart indicating operations of the program circuit 100 in accordance with the first embodiment. Each of the control signals in the present embodiment is a digital signal indicating a logical H or a logical L. The potential of each control signal, when the control signal indicates a logical H, is generally at the same potential as that of the driving voltage VCC of the ferroelectric memory device 500. Also, the potential of each control signal, when the control signal indicates a logical L, is at a grounding potential, in other words, 0V.

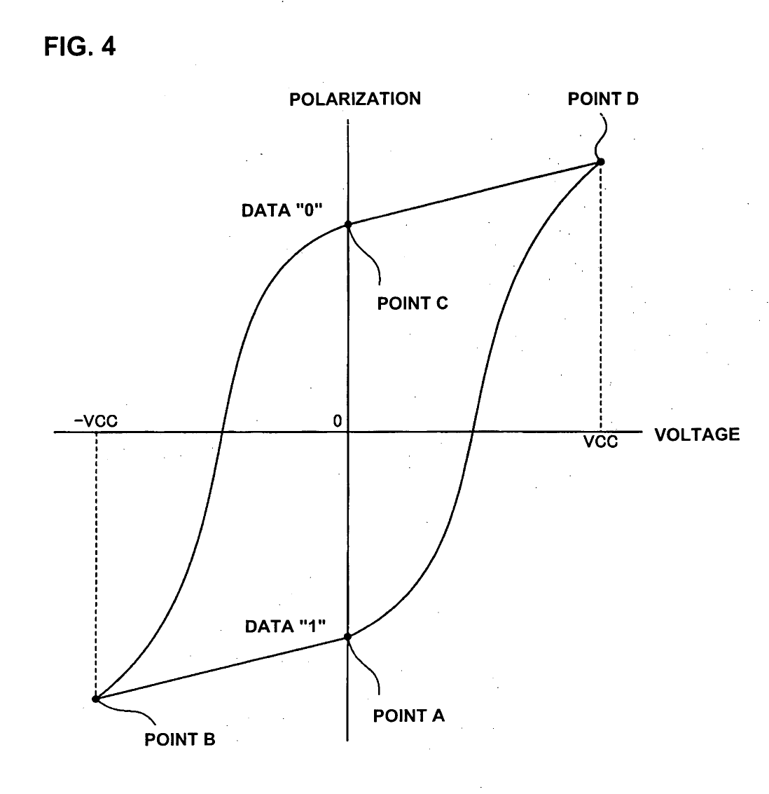

FIG. 4 is a diagram indicating hysteresis characteristics of the first ferroelectric capacitor 122 and the second ferroelectric capacitor 124. In the figure, an axis of ordinates indicates polarizations of the first ferroelectric capacitor 122 and the second ferroelectric capacitor 124, and an axis of abscissas indicates voltages that are applied to the first ferroelectric capacitor 122 and the second ferroelectric capacitor 124. In the figure, when the potential on one ends of the first ferroelectric capacitor 122 and the second ferroelectric capacitor 124 is higher than the potential on the other ends thereof, voltages applied to the first ferroelectric capacitor 122 and the second ferroelectric capacitor 124 are expressed in the positive side.

Also, in the present embodiment, data “0” is written in the first ferroelectric capacitor 122, and data “1” is written in the second ferroelectric capacitor 124. In other words, the first ferroelectric capacitor 122 has a capacity C0 based on its paraelectric characteristic, and the second ferroelectric capacitor 124 has a capacity C1 that is greater than the capacity C0 as a capacity based on its paraelectric characteristic. Also, because the voltage that is applied to the first ferroelectric capacitor 122 and the second ferroelectric capacitor 124 is 0V in an initial state, their hysteresis characteristics are at point C and point A, respectively. Operation of the program circuit of the present embodiment are described below with reference to FIG. 2 through FIG. 4.

First, in an initial state, the control signal RE indicates a logical H. Accordingly, the n-type MOS transistors 142 and 144 are conductive, such that the first terminal 116 and the ferroelectric capacitor 122 are electrically connected, and the second terminal 118 and the second ferroelectric capacitor 124 are also electrically connected. In other words, the capacity C0 is appended to the first terminal 116 by the first ferroelectric capacitor 122, and the capacity C1 is appended to the second terminal 118 by the second ferroelectric capacitor 124.

When feeding of a power supply voltage to the flip-flop 110 is started, the power supply voltage supplied to the first inverter 112 and the second inverter 114 gradually rises. Also, because the input potential on the first inverter 112 and the second inverter 114 is 0V at this moment, the output potential on the first inverter 112 and the second inverter 114 also rises with the rise of the power supply voltage. In other words, the potential on the first terminal 116 and the second terminal 118 rises. It is noted here that the power supply voltage is a voltage of the power supply that operates the flip-flop 110, which is, for example, a driving voltage VCC.

At this moment, the capacity C0 is appended by the first ferroelectric capacitor 122 to the first terminal 116, and the capacity C1 that is greater than the capacity C0 is appended by the second ferroelectric capacitor 124 to the second terminal 118. In other words, to raise the potential on the first terminal 116 and the second terminal 118, the capacities C0 and C1 need to be charged. In the present embodiment, because a greater capacity is appended to the second terminal 118 than to the first terminal, the potential on the first terminal 116 rises quicker than the potential on the second terminal 118. Accordingly, the potential on the first terminal 116 reaches a threshold voltage Vt of the first inverter 112 and the second inverter 114 earlier than the potential on the second terminal 118 does. It is noted here that the threshold voltage Vt of an inverter is a voltage at which the logical value of an output of the inverter changes.

When the potential on the first terminal 116 reaches the threshold voltage Vt, the output of the first inverter 112 changes to a logical L. Accordingly, when the potential on the first terminal 116 reaches the threshold voltage Vt, the potential on the second terminal 118 falls to 0V. Also, when the potential on the second terminal 118 falls to 0V, the output from the second inverter 114 would change to a logical H. Accordingly, when the potential on the first terminal 116 reaches the threshold voltage Vt, the potential on the first terminal 116 becomes to be generally the same potential of the power supply voltage. By this, the flip-flop 110 retains memory data in which the potential on the first terminal 116 is a logical H, and the logical value on the second terminal 118 is a logical L. By the operations described above, memory data stored in the storage section 120 is read out, and the memory data is retained on the flip-flop 110.

Next, the control section 560 (see FIG. 1) changes the control signal OE to a logical H, thereby making the transfer gate 164 conductive. By this, the NAND circuit 166 outputs an output signal OUT indicating the memory data that is retained by the flip-flop 110. In other words, the output section 160 outputs a logical H as a logical value indicating the memory data, because the logical value on the second terminal 118 is a logical L. It is noted that, in the present embodiment, the logical value of the output signal OUT is continuously maintained at a logical H, because the logical value of the output signal OUT before the control signal OE is changed to a logical H is also a logical H. By the operation described above, the memory data retained by the flip-flop 110 is outputted from the output section 160 as the output signal OUT.

While the output section 160 is outputting the output signal OUT indicating the memory data, the storage section 120 may preferably be electrically cut off from the flip-flop 110. In the present embodiment, the control section 560 changes the control signal RE to a logical L to make the n-type MOS transistors 142 and 144 nonconductive, thereby electrically cutting off the storage section 120 from the flip-flop 110. Also, when the control signal RE changes to a logical L, the n-type MOS transistors 132 and 134 become conductive. Accordingly, one ends of the first ferroelectric capacitor 122 and the second ferroelectric capacitor 124 are grounded, such that their potential becomes to be 0V. Also, because the control signal PL is also at a logical L, the potential on the other ends of the first ferroelectric capacitor 122 and the second ferroelectric capacitor 124 becomes to be 0V. Accordingly, the voltage applied to the first ferroelectric capacitor 122 and the second ferroelectric capacitor 124 becomes to be generally 0V.

Next, a rewriting operation for storing in the storage section 120 memory data that is the same as the memory data retained by the flip-flop 110 is conducted. The rewriting operation may preferably be conducted after the output section 160 starts outputting the output signal OUT by the time when feeding of the power supply voltage to the flip-flop 110 is completed.

First, when the control section 560 changes the control signal RE to a logical H, the storage section 120 and the flip-flop 110 are electrically connected. In other words, one end of the first ferroelectric capacitor 122 is electrically connected to the first terminal 116, and one end of the second ferroelectric capacitor 124 to the second terminal 118. Here, because the flip-flop 110 retains memory data through setting the logical value on the first terminal 116 to be a logical H, and the logical value on the second terminal 118 to be a logical L, the potential on one end of the ferroelectric capacitor 122 becomes to be VCC, and the potential on one end of the ferroelectric capacitor 124 becomes to be 0V.

At this moment, the logical value of the control signal PL is a logical L. In other words, because the potential on the first ferroelectric capacitor 122 is 0V, the voltage applied to the first ferroelectric capacitor 122 becomes to be −VCC. Accordingly, referring to FIG. 4, because the hysteresis characteristic of the first ferroelectric capacitor 122 moves from point C to point D, data “0” is rewritten in the first ferroelectric capacitor 122.

Next, the control section 560 changes the control signal PL to a logical H, in other words, changes the potential on the other ends of the first ferroelectric capacitor 122 and the second ferroelectric capacitor 124 to VCC. At this moment, because the potential on the one end of the second ferroelectric capacitor 124 is 0V, the voltage applied to the second ferroelectric capacitor 124 becomes to be −VCC. Accordingly, referring to FIG. 4, because the hysteresis characteristic of the second ferroelectric capacitor 124 moves from point A to point B, data “1” is rewritten in the second ferroelectric capacitor 124. On the other hand, because the voltage applied to the first ferroelectric capacitor 122 is almost 0V, its hysteresis characteristic moves to point C. Accordingly, the data “0” rewritten in the first ferroelectric capacitor 122 is continuously retained as it is. By the operation described above, memory data that is the same as the memory data retained in the flip-flop 110 is stored in the storage section 120 again.

Next, a writing operation for storing desired memory data in the storage section 120 is described. In an example described below, an operation to store memory data that is different from memory data stored in the storage section 120 in the storage section 120, in other words, an operation to write data “1” in the first ferroelectric capacitor 122, and data “0” in the second ferroelectric capacitor 124, is described.

First, in a state in which the storage section 120 and the flip-flop 110 are electrically connected, the control section 560 changes the control signal IE to a logical H, thereby making the transfer gate 154 conductive. Then, the control signal 560 changes the potential of the control signal IN to 0V, thereby bringing the potential on the first terminal 116 to 0V. By this, the output of the first inverter 112 becomes to be a logical H, such that the potential on the second terminal 118 becomes to be VCC and the output of the second inverter 114 becomes to be a logical L.

At this moment, because the logical value of the control signal PL is a logical L, in other words, because the potential on the other end of the second ferroelectric capacitor 124 is 0V, the voltage applied to the second ferroelectric capacitor 124 becomes to be VCC. Accordingly, referring to FIG. 4, because the hysteresis characteristic of the second ferroelectric capacitor 124 moves to point D, data “0” is written anew in the second ferroelectric capacitor 124.

Next, the control section 560 changes the control signal PL to a logical L, in other words, it changes the potential on the other ends of the first ferroelectric capacitor 122 and the second ferroelectric capacitor 124 to VCC. At this moment, because the potential on the one end of the first ferroelectric capacitor 122 is 0V, the voltage applied to the first ferroelectric capacitor 122 becomes to be −122. Accordingly, referring to FIG. 4, because the hysteresis characteristic of the first ferroelectric capacitor 122 moves to point B, data “1” is written anew in the first ferroelectric capacitor 122. On the other hand, because the voltage applied to the second ferroelectric capacitor 124 is almost 0V, its hysteresis characteristic moves to point A. Accordingly, the data “0” written in the second ferroelectric capacitor 124 is continuously retained as it is. By the operation described above, memory data that is different from the memory data retained at the flip-flop 110 is stored anew in the storage section 120.

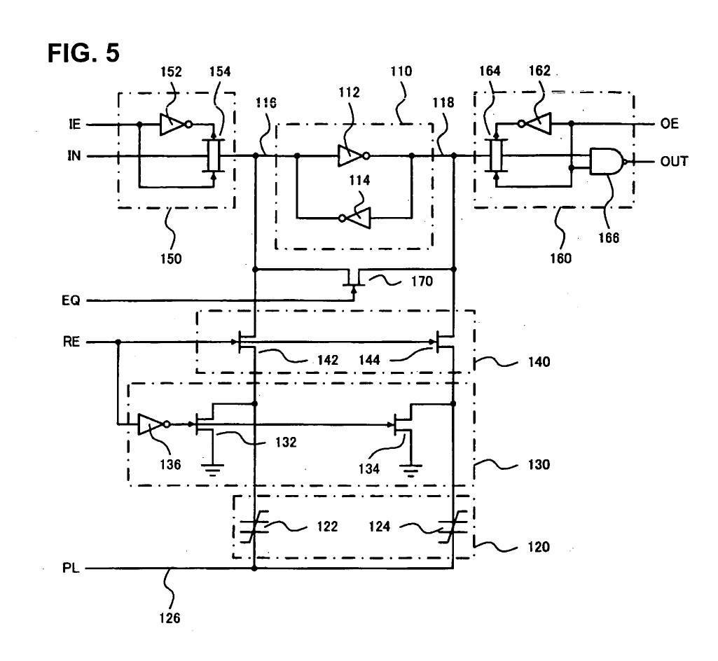

FIG. 5 is a diagram indicating a program circuit 100 in accordance with a second embodiment. The program circuit 100 of the second embodiment is described below, focusing on features different from those of the first embodiment. It is noted that components appended with the same reference numbers as those of the first embodiment have functions similar to those of the first embodiment.

The program circuit 100 in accordance with the second embodiment has a structure that is further equipped with a short-circuit section 170 in addition to the structure of the first embodiment. The short-circuit section 170 short-circuits the first terminal 116 and the second terminal 118. In other words, the short-circuit section 170 brings the potential on the first terminal 116 and the potential on the second terminal 118 to generally the same potential.

In the present embodiment, the short-circuit section 170 has a structure having an n-type MOS transistor. More specifically, one of the source and the drain of the n-type MOS transistor is electrically connected to the first terminal 116, and the other is electrically connected to the second terminal 118. Then the n-type MOS transistor controls, based on the potential of a control signal EQ supplied to its gate, as to whether or not the first terminal 116 and the second terminal 118 are to be short-circuited.

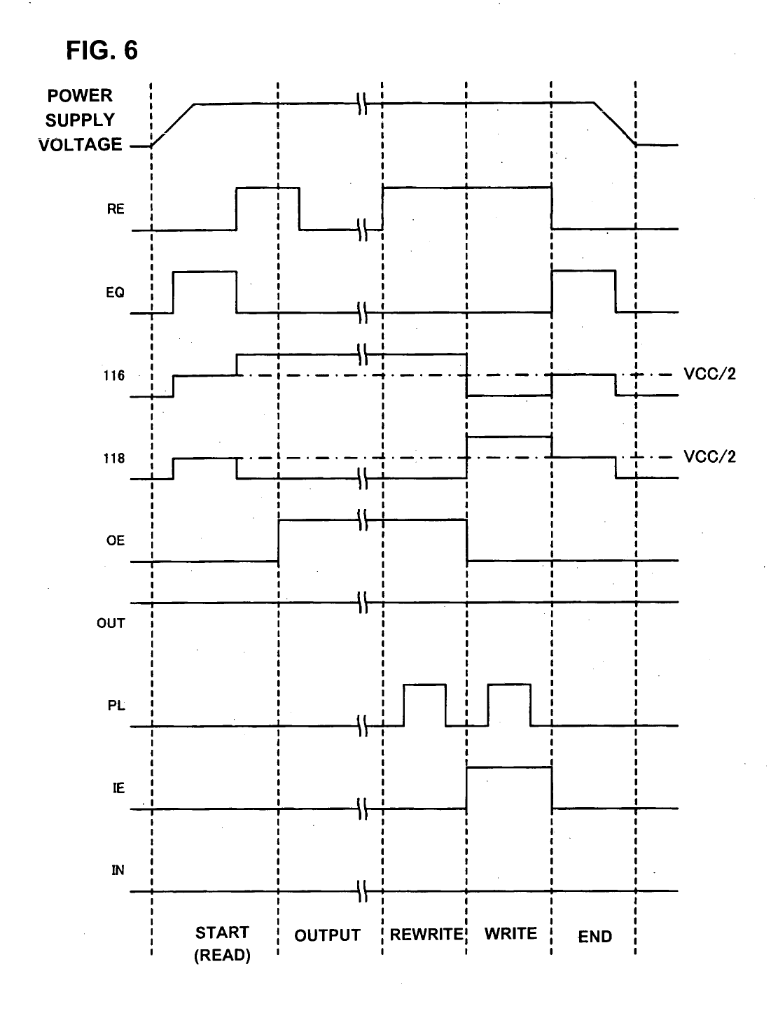

FIG. 6 is a timing chart indicating operations of the program circuit 100 in accordance with the second embodiment. Operations of the program circuit 100 in accordance with the present embodiment are described with reference to FIG. 5 and FIG. 6. It is noted that the program circuit 100 of the present embodiment differs from the first embodiment mainly in its reading operation, and therefore the operations of the program circuit 100 in accordance with the present embodiment are described, focusing on its reading operation.

First, in an initial state, the control signal RE indicates a logical L. Accordingly, the flip-flop 110 is electrically cut off from the storage section 120. Also, the control section 560 changes the control signal EQ to a logical H, before or after the power supply voltage is fed to the flip-flop 110, thereby short-circuiting the first terminal 116 and the second terminal 118. In the state in which the first terminal 116 and the second terminal 118 are short-circuited, and when the power supply voltage is fed to the flip-flop 110, potentials of outputs from the first inverter 112 and the second inverter 114 both become to be potentials between 0V and VCC. Because the first inverter 112 and the second inverter 114 in the present embodiment have generally the same structure, the potentials of the outputs from the first inverter 112 and the second inverter 114 become to be potentials that are about a half of VCC.

Next, the control section 560 changes the control signal RE to a logical H. By this, one ends of the first ferroelectric capacitor 122 and the second ferroelectric capacitor 124 are electrically connected to first terminal 116 and the second terminal 118, respectively, whereby a capacity C0 is appended to the first terminal 116 by the first ferroelectric capacitor 122, and a capacity C1 that is greater than the capacity C0 is appended to the second terminal 118 by the second ferroelectric capacitor 124.

Also, the control section 560 changes the control signal EQ to a logical L. The control section 560 may preferably change the control signal EQ to a logical L after the operation of the flip-flop 110 has become stable. Also, the control section 560 may preferably change the logical value of the control signal EQ according to the timing at which the flip-flop 110 and the storage section 120 are electrically connected. Also, more preferably, the control section 560 may change the control signal EQ to a logical H generally at the same time as the aforementioned timing. When the control signal EQ changes to a logical L, the n-type MOS transistor composing the short-circuit section 170 becomes nonconductive, and therefore the first terminal 116 and the second terminal 118 are electrically cut off from each other.

By this, when the control signal RE changes to a logical H, the potential on the second terminal 118 falls greater than the potential on the first terminal 116, such that the output of the second inverter 114 becomes to be a logical H, and the output of the first inverter 112 becomes to be a logical L. By this, the flip-flop 110 retains memory data in which the potential on the first terminal 116 is at a logical H, and the logical value on the second terminal 118 is at a logical L. By the operation described above, memory data stored in the storage section 120 is read out, and the memory data is retained at the flip-flop 110.

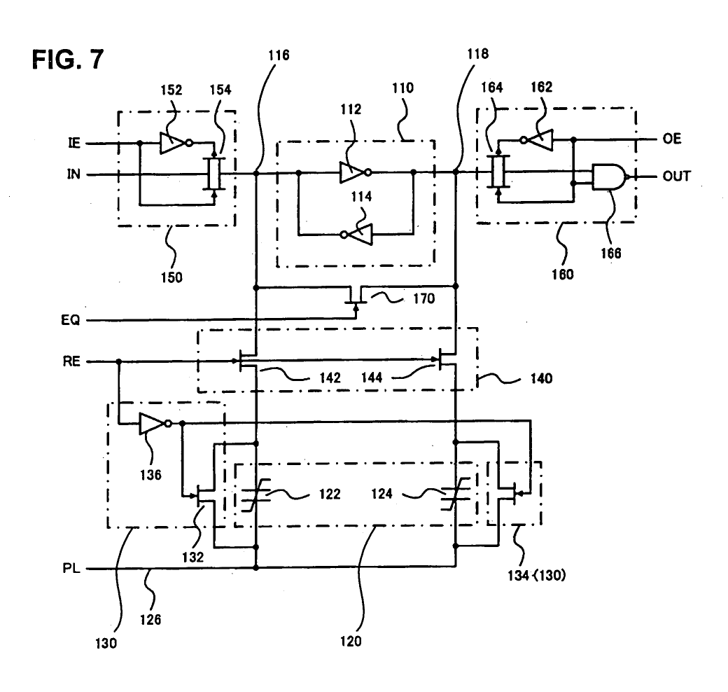

FIG. 7 is a diagram indicating a program circuit 100 in accordance with a third embodiment. The program circuit 100 in accordance with the third embodiment is described below, focusing on features different from those of the first embodiment and the second embodiment. It is noted that components appended with the same reference numbers as those of the first embodiment and/or the second embodiment have functions similar to those of the embodiments. It is noted that the control section 560 controls the program circuit 100 of the present embodiment in a similar manner as the second embodiment.

The program circuit 100 in accordance with the third embodiment differs from the second embodiment in the structure of its discharge section 130. In the present embodiment, the discharge section 130 brings one ends and the other ends of the first ferroelectric capacitor 122 and the second ferroelectric capacitor 124 to generally the same potential. Also, when the storage section 120 is electrically cut off from the flip-flop 110, the discharge section 130 may preferably bring the potentials on the one ends and the other ends of the first ferroelectric capacitor 122 and the second ferroelectric capacitor 124 to generally the same potential.

More specifically, an n-type MOS transistor 132 that is an example of a switch, which composes the discharge section 130, has one of its source and drain electrically connected to one end of the first ferroelectric capacitor 122, and the other electrically connected to the other end thereof. Also, an n-type MOS transistor 134 that is an example of a switch has one of its source and drain electrically connected to one end of the second ferroelectric capacitor 124, and the other electrically connected to the other end thereof. In other words, the n-type MOS transistors 132 and the 134 are composed to short-circuit one ends and the other ends of the first ferroelectric capacitor 122 and the second ferroelectric capacitor 124, respectively, based on the potential of the control signal RE.

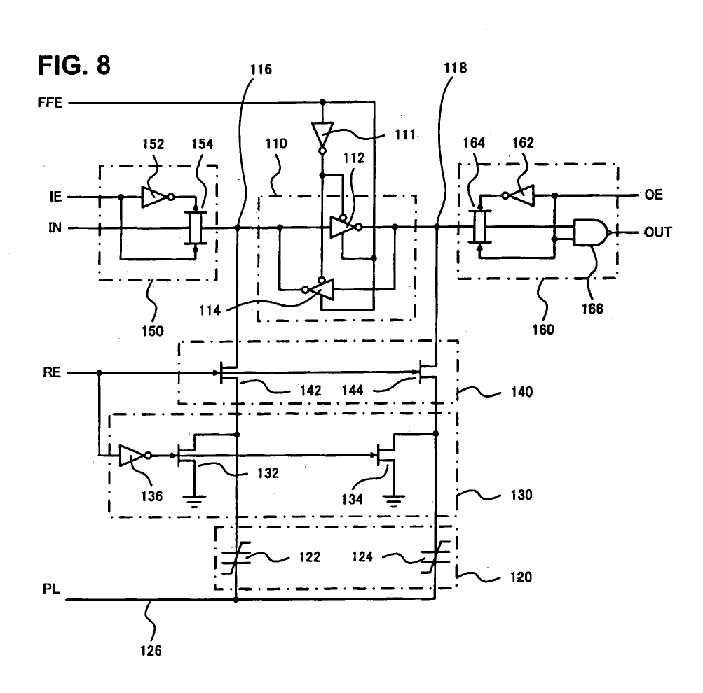

FIG. 8 is a diagram indicating a program circuit 100 in accordance with a fourth embodiment. The program circuit 100 in accordance with the fourth embodiment is described below, focusing on features different from those of the first embodiment through the third embodiment. It is noted that components appended with the same reference numbers as those of the first embodiment, the second embodiment and/or the third embodiment have functions similar to those of the embodiments.

The program circuit 100 in accordance with the fourth embodiment differs from the other embodiments in the structure of its flip-flop 110. In the present embodiment, a first inverter 112 and a second inverter 114 that compose the flip-flop 110 are clocked inverters. Also, the control section 560 supplies to the flip-flop 110 a control signal FFE that is a signal for controlling operations of the first inverter 112 and the second inverter 114. Also, the program circuit 100 is further equipped with a sixth inverter 111 that receives the control signal FFE as an input, and supplies an inverted signal that is the inverted control signal to the first inverter 112 and the second inverter 114.

In the present embodiment, the first inverter 112 and the second inverter 114 are composed such that a signal received as an input is inverted and outputted when the logical value of the control signal FFE is a logical H, and that an output becomes to have a high impedance when the logical value of the control signal FFE is a logical L. In other words, the first inverter 112 and the second inverter 114 in accordance with the present embodiment are composed to operate when the logical value of the control signal FFE is a logical H.

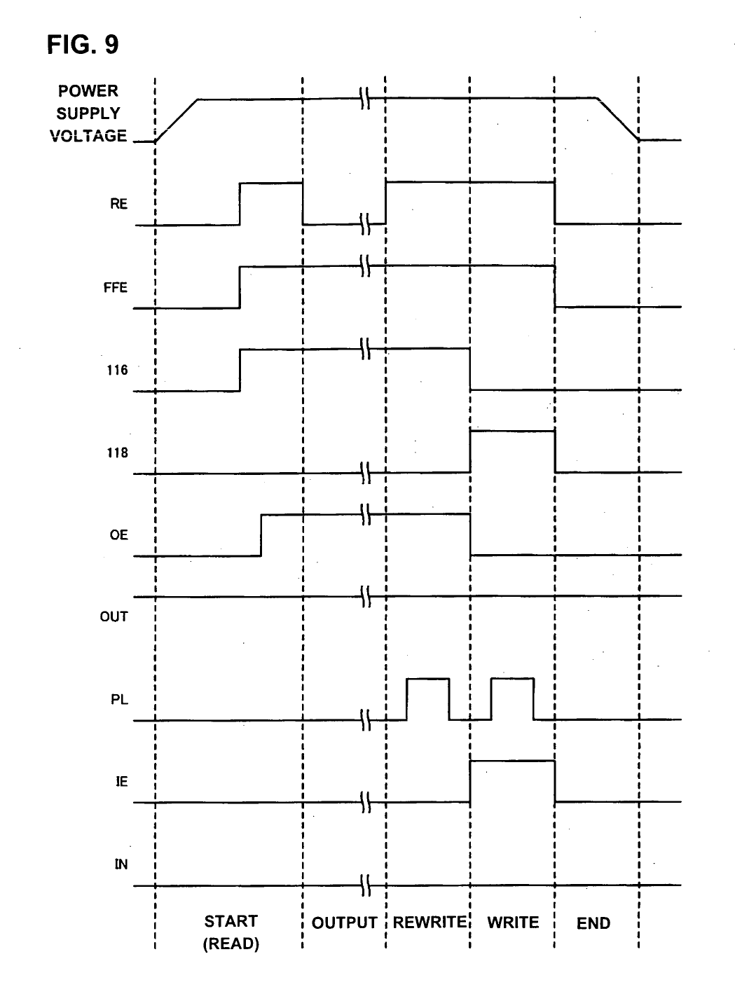

FIG. 9 is a timing chart indicating operations of the program circuit in accordance with the fourth embodiment. Referring to FIG. 8 and FIG. 9, operations of the program circuit 100 of the present embodiment are described. It is noted that, because the program circuit 100 of the present embodiment differs from the first embodiment through the third embodiment mainly in its reading operation, the program circuit 100 of the present embodiment is described, focusing on its reading operation.

First, the control section 560 changes the control signal RE indicating a logical L to a logical H. By this, one ends of the first ferroelectric capacitor 122 and the second ferroelectric capacitor 124 are electrically connected to the first terminal 116 and the second terminal 118, respectively, such that a capacity C0 is appended to the first terminal 116 by the first ferroelectric capacitor 122, and a capacity C1 that is greater than the capacity C0 is appended to the second terminal 118 by the second ferroelectric capacitor 124.

Also, the control section 560 changes the control signal FFE from a logical L to a logical H. The control section 560 may preferably change the control signal FFE from a logical L to a logical H, after the control signal RE has changed to a logical H. In this case, the control section 560 may change the control signal FFE from a logical L to a logical H, in synchronism with the timing to change the logical value of the control signal RE.

Also the control section 560 may preferably change the control signal FFE to a logical H after the power supply voltage fed to the flip-flop 110 has elevated to VCC. When the control signal FFE changes to a logical H, the first inverter 112 and the second inverter 114 both output a logical H, because the potential on the first terminal 116 and the second terminal 118 before the control signal FFE changes to a logical H is 0V.

Here, because the capacity C1, which is greater than that appended to the first terminal 116, is appended to the second terminal 118, the potential of an input to the first inverter 112, in other words, on the first terminal 116, rises quicker than the potential of an input to the second inverter 114, in other words, on the second terminal 118. In other words, the potential of the input to the first inverter 112 reaches the threshold voltage Vt earlier than the potential of the input to the second inverter 114 does. Accordingly, when the control signal FFE changes to a logical H, the output of the second inverter 114 becomes to be a logical H, and the output of the first inverter 112 becomes to be a logical L. By this, the flip-flop 110 retains memory data in which the potential on the first terminal 116 is a logical H, and the logical value on the second terminal 118 is a logical L. By the operation described above, memory data stored in the storage section 120 is read out, and the memory data is retained at the flip-flop 110.

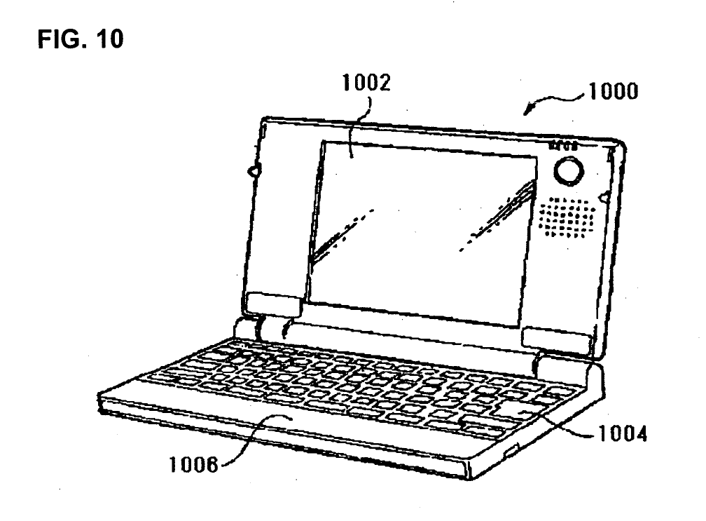

FIG. 10 is a perspective view showing a structure of a personal computer 1000, which is an example of an electronic apparatus in accordance with an embodiment of the present invention. In FIG. 10, the personal computer 1000 has a structure equipped with a display panel 1002 and a main body 1006 having a keyboard 1004. As storage medium, and in particular, a nonvolatile memory of the main body 1006 of the personal computer 1000, a semiconductor device equipped with a storage circuit in accordance with the present invention is used.

The embodiment examples and application examples described above with reference to the embodiments of the present invention may be appropriately combined depending on the usages, or may be used with changes and/or improvements added thereto. The present invention is not limited to the descriptions of the embodiments above. It is clear from the description in the scope of patent claims that modes created by such combinations, changes and/or improvements can be included in the technical scope of the present invention.

1. A storage circuit characterized in comprising:
a flip-flop having a first terminal and a second terminal;
a first ferroelectric capacitor that gives a first capacity to the first terminal;
a second ferroelectric capacitor that gives a second capacity different from the first capacity to the second terminal; and
a voltage source that starts supplying a driving voltage for driving the flip-flop to the flip-flop in which the first capacity and the second capacity are given to the first terminal and the second terminal, respectively.

2. A storage circuit characterized in comprising:
a flip-flop having a first terminal and a second terminal;
a first ferroelectric capacitor that gives a first capacity to the first terminal;
a second ferroelectric capacitor that gives a second capacity different from the first capacity to the second terminal; and
a short-circuit section that controls as to whether or not the first terminal and the second terminal are to be electrically connected.

3. A storage circuit according to claim 2, characterized in further comprising a connecting section that controls as to whether or not the flip-flop is to be electrically connected to the first ferroelectric capacitor and the second ferroelectric capacitor, wherein
the short-circuit section electrically cuts off the first terminal and the second terminal corresponding to a timing at which the connecting section electrically connects the flip-flop to the first ferroelectric capacitor and the second ferroelectric capacitor.

4. A storage circuit characterized in comprising:
a first clocked inverter having an input terminal and an output terminal;
a second clocked inverter that inverts a signal outputted from the output terminal and supplies the signal to the input terminal;
a first ferroelectric capacitor that gives a first capacity to the input terminal;
a second ferroelectric capacitor that gives a second capacity different from the first capacity to the output terminal; and
a control section that controls as to whether or not the first clocked inverter and the second clocked inverter are to be operated.

5. A storage circuit according to claim 4, characterized in further comprising a voltage source that supplies a driving voltage to the first clocked inverter and the second clocked inverter, wherein
the control section operates the first clocked inverter and the second clocked inverter after a potential of the driving voltage exceeds a threshold voltage of the first clocked inverter and the second clocked inverter.

6. A storage circuit according to claim 1, characterized in further comprising a discharge section that brings both ends of the first ferroelectric capacitor and the second ferroelectric capacitor to generally an identical potential.

7. A storage circuit characterized in comprising:
a flip-flop having a first terminal and a second terminal;
a first ferroelectric capacitor that gives a first capacity to the first terminal;
a second ferroelectric capacitor that gives a second capacity different from the first capacity to the second terminal;
a first switch that short-circuits both ends of the first ferroelectric capacitor; and
a second switch that short-circuits both ends of the second ferroelectric capacitor.

8. A storage circuit according to claim 1, characterized in that complementary data are written in the first ferroelectric capacitor and the second ferroelectric capacitor.

9. A semiconductor device characterized in comprising a storage circuit recited in claim 1.

10. An electronic apparatus characterized in comprising a semiconductor device recited in claim 9.

11. A driving method for driving a storage circuit equipped with a flip-flop having a first terminal and a second terminal, the driving method characterized in comprising:
a step of giving a first capacity to the first terminal;
a step of giving a second capacity different from the first capacity to the second terminal; and
a step of starting supplying a driving voltage to the flip-flop.

12. A driving method according to claim 11, characterized in that
the storage circuit is equipped with a first ferroelectric capacitor having the first capacity and a second ferroelectric capacitor having the second capacity,
the step of giving the first capacity includes a step of electrically connecting the first terminal and the first ferroelectric capacitor, and
the step of giving the second capacity includes a step of electrically connecting the second terminal and the second ferroelectric capacitor.
